(19) United States
(12) Patent Application Publication
(10) Pub. No.: US 2026/0341354 A1
(43) Pub. Date: Oct. 29, 2026

(54) PHASE CHANGE NONVOLATILE MEMORY UNIT CELL WITH LOW DATA WRITE LATENCY

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/187,899

(22) Filed: Apr. 23, 2025

(51) Int. Cl. G11C 13/00

(52) U.S. Cl. CPC G11C 13/004; G11C 13/0004; G11C 2013/0045; G11C 2213/35

(57) ABSTRACT

The technology described herein is directed towards a phase change material-based unit cell for use in a phase change memory device, such as a phase change memory array. The phase change material-based unit cell includes phase change material (e.g., Sb₂Te₃) doped with percentages of carbon and platinum. The doped phase change material reduces the time taken to write a one-bit value to the phase change material (the SET time), making it comparable to the RESET time taken to write a zero-bit, which is a drawback of traditional phase change memory. In one implementation, the doped phase change material is incorporated into a unit cell design with improved heat management for efficient phase transition by incorporating a thermally resistive dielectric layer that minimizes heat loss to the substrate during write operations. The faster performance of the phase change memory cell facilitates usage in nonvolatile memory in computers.

### RELATED APPLICATIONS

The subject patent application is related to U.S. patent application Ser. No. ______, filed ______, entitled “SCALABLE NONVOLATILE IN-LINE PHASE-CHANGE MEMORY CROSSBAR ARRAY WITH HIGH-SPEED ACTUATION” (docket no. 140419.01/DELLP1529US), U.S. patent application Ser. No. ______, filed ______, entitled “NONVOLATILE PHASE-CHANGE MEMORY ARCHITECTURE WITH IN-MEMORY COMPUTATION” (docket no. 140420.01/DELLP1517US), and U.S. patent application Ser. No. ______, filed ______, entitled “BINARY-TO-STOCHASTIC CONVERTER LEVERAGING MULTI-STATE RESISTANCE CHANGE IN PHASE CHANGE MATERIALS” (docket no. 140421.01/DELLP1518US), the entireties of which patent application are hereby incorporated by reference herein.

### BACKGROUND

Dynamic random-access memory (DRAM) is a type of semiconductor memory that stores each bit of data in a memory cell, often via a capacitor and a transistor based on metal-oxide-semiconductor (MOS) technology. DRAM has generally sufficed to meet the capacity and performance demands of computing device memory in various applications. However, scaling DRAM further has reached practical fabrication limits, leading to increased leakage power and inadequate capacity for many modern applications.

### BRIEF DESCRIPTION OF THE DRAWINGS

The technology described herein is illustrated by way of example and not limited to the accompanying figures in which like reference numerals indicate similar elements and in which:

FIG. 1 is a cross-sectional view of an example phase change material-based unit memory cell fabrication stack, in accordance with various embodiments and implementations of the subject disclosure.

FIG. 2 top view of the example phase change unit memory cell device of FIG. 1 with example dimensions highlighted, in accordance with various embodiments and implementations of the subject disclosure.

FIG. 3 is a cross-sectional view of the example phase change material-based unit memory cell highlighting example components, in accordance with various embodiments and implementations of the subject disclosure.

FIG. 4 is a representation of programmable pulses for SET (e.g., write “1”), RESET (e.g., write “0”), and READ (read “1” or “0”) operations in the example phase change memory unit cell, in accordance with various embodiments and implementations of the subject disclosure.

FIG. 5 is a representation of the example heat flow and phase transition in the example phase change memory unit cell in response to application of a RESET pulse, in accordance with various embodiments and implementations of the subject disclosure.

FIG. 6 is a representation of the example heat flow and phase transition in the example phase change memory unit cell in response to application of a SET pulse, in accordance with various embodiments and implementations of the subject disclosure.

FIG. 7 is a representation of the example heat flow and phase transition in the example phase change memory unit cell in response to application of a READ pulse, in accordance with various embodiments and implementations of the subject disclosure.

FIG. 8 is a representation of an example simulation setup for an example phase change memory unit cell, showing the use of symmetry conditions to model a quarter section, in accordance with various embodiments and implementations of the subject disclosure.

FIG. 9 is a series of three-dimensional (3D) simulation representations showing the heating and cooling phases over a 24 nanosecond period in response to the application of a programmable pulse, in accordance with various embodiments and implementations of the subject disclosure.

FIG. 10 is a diagrammatic top view representation of an example phase change memory unit cell showing connections between the control line, access device, wordlines, and bitlines, in accordance with various embodiments and implementations of the subject disclosure.

FIG. 11 is a diagrammatic top view representation of an example phase change memory unit cell showing components, and a zoomed-in representation with dimensions and corresponding metallization layers indicated, in accordance with various embodiments and implementations of the subject disclosure.

FIG. 12 is a representation of a monolithically integrated phase change memory array of unit cells, suitable for advanced CMOS-compatible fabrication processes, in accordance with various embodiments and implementations of the subject disclosure.

FIG. 13 is a representation of example physical structure and simulation of a phase change memory unit cell, illustrating structural details and thermal response to an applied pulse, and a 3D rendered finite element model showing temperature distribution at the nanoscale, in accordance with various embodiments and implementations of the subject disclosure.

FIG. 14 is a representation of an example phase change memory in-memory compute architecture, in accordance with various embodiments and implementations of the subject disclosure.

FIG. 15A shows schematic representations of stochastic arithmetic circuits, including a multiplier (AND gate, left side) and Adder (MUX circuit, right side), in accordance with various embodiments and implementations of the subject disclosure.

FIG. 15B is a representation of an example flow sequence for converting convolutional neural network operands from binary to stochastic format, and storing them into a compute partition with the example phase change memory architecture of FIG. 14, in accordance with various embodiments and implementations of the subject disclosure.

FIG. 16 is a representation of an example flow sequence for performing a bit-parallel AND operation between two stochastic operands stored in phase change memory rows within a compute partition, in accordance with various embodiments and implementations of the subject disclosure.

FIG. 17 is a graphical representation of the example resistance difference between SET (crystalline) and RESET (amorphous) states in a phase change memory cell, showing a significant resistance gap useable to represent binary data, in accordance with various embodiments and implementations of the subject disclosure.

FIG. 18 is a representation of an example phase change memory cell array with shared sense amplifiers that read stored data by comparing voltage drops across the cells against a reference voltage (V_{REF}), in accordance with various embodiments and implementations of the subject disclosure.

FIG. 19 is a representation of an example functional block diagram of a binary-to-stochastic converter (BSC) using a phase change memory-based reference voltage generator, in accordance with various embodiments and implementations of the subject disclosure.

FIG. 20 is a flow diagram showing example operations related to writing information to a phase change material memory cell via a set energy pulse or a reset energy pulse to a heating element of the memory cell, and reading the memory cell based on the conductive or nonconductive state of the phase change material, in accordance with various aspects and implementations of the subject disclosure.

### DETAILED DESCRIPTION

Various implementations and embodiments of the technology described herein are generally directed towards a phase change material-based memory unit cell that can switch between amorphous and crystalline phases, which each exhibit distinct electrical properties suitable for data storage. A RESET pulse (operation) transitions the material to the amorphous (nonconductive) state, and a SET pulse (operation) transitions the material to the crystalline (conductive) state.

Note that traditional phase change materials (chalcogenides), such as Ge₂Sb₂Te₅ (germanium (Ge), antimony (Sb), and tellurium (Te), sometimes referred to as GST) thin film, have limitations, particularly in that the SET operation is relatively much longer than the RESET operation, which results in longer write latencies. Indeed, phase change memory, which relies on the phase transition properties of material to store data, is one candidate to replace DRAM, as phase change memory is noted for its nonvolatility, scalability, low standby power consumption, and comparable read latency. However a significant challenge hindering the adoption of main memory based on conventional phase change memory is the asymmetric write latency between SET and RESET operations; for example, the SET operation, which writes a “1” to a phase change memory cell, currently takes two-to-five times longer (with two-to-four times lower-amplitude) energy pulses than the RESET operation, which writes a “0”. When writing a page or line of data to phase change memory, the extended duration of the SET operation results in increased write latency, limiting the overall write performance of phase change memory systems.

Described herein is carbon and platinum doping of Sb₂Te₃ (CₓPt_{y}Sb₂Te₃), e.g., where x is 15 to 20 percent and y is 3 to 5 percent, as a new material for phase change memory. The doped material reduces the SET time, making it comparable to the RESET time, thus addressing the primary drawback of traditional phase change memory. In one implementation, the doped phase change material is incorporated into a unit cell design with improved heat management for efficient phase transition. Thermal simulations confirm the effectiveness of this design in achieving faster transitions between the two states, making such doped phase change memory a more viable option for future memory technologies.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some practical limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

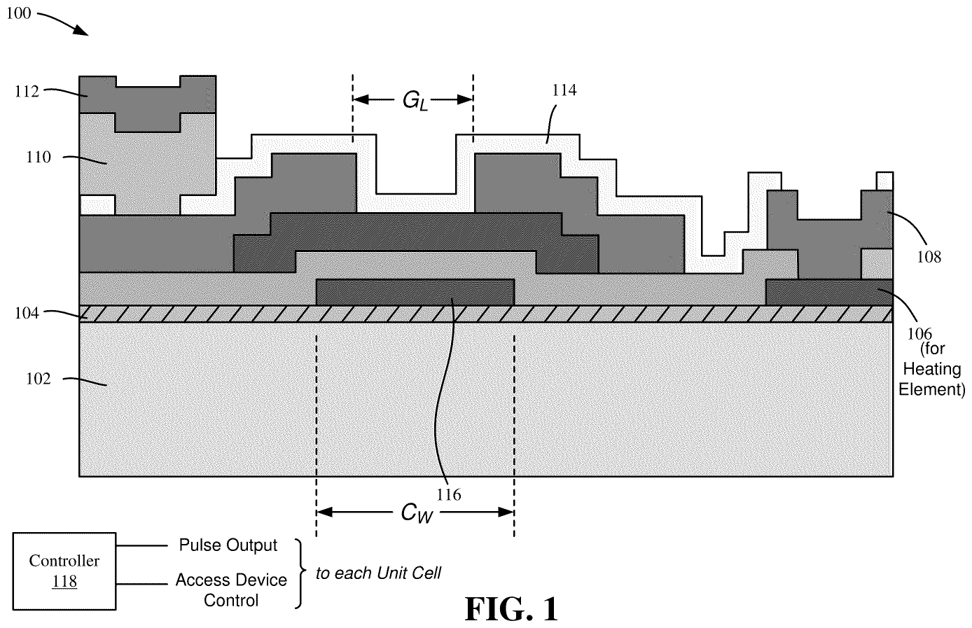

FIG. 1 shows a cross-sectional view of one implementation of an example phase change memory unit cell 100 fabrication stack. The unit cell 100 represents a fundamental element in phase change memory. Starting from the bottom, the stack includes a substrate 102, which supports the entire structure. Above this, a thermally resistive dielectric layer 104 ensures that heat is confined to the phase change memory section and does not sink into the substrate 102. The example stack also contains multiple metallization levels, namely metallization level 1 (106) for the control mechanism (to the heating element), metallization level 2 (108) for bitlines, metallization level 3 (110) for wordlines, and metallization level 4 for a contact for an access device (e.g., an NMOS transistor, a BJT, or a PN-junction diode).

Additionally, thermally conductive dielectric layers 114 are included to manage heat dissipation, ensuring efficient operation. The heat from the heating element, when selectively applied via an energy (voltage or current SET or RESET) pulse at the bitline, determines the conductive or nonconductive state of the phase change material 116. As described herein, whether or not the unit cell is activated with respect to obtaining a voltage pulse at the bitline that heats the heating element depends on access device control by a controller 118 or the like, which also can output the SET or RESET pulse to the bitline, or the READ pulse to the phase change material 118, via the bitline.

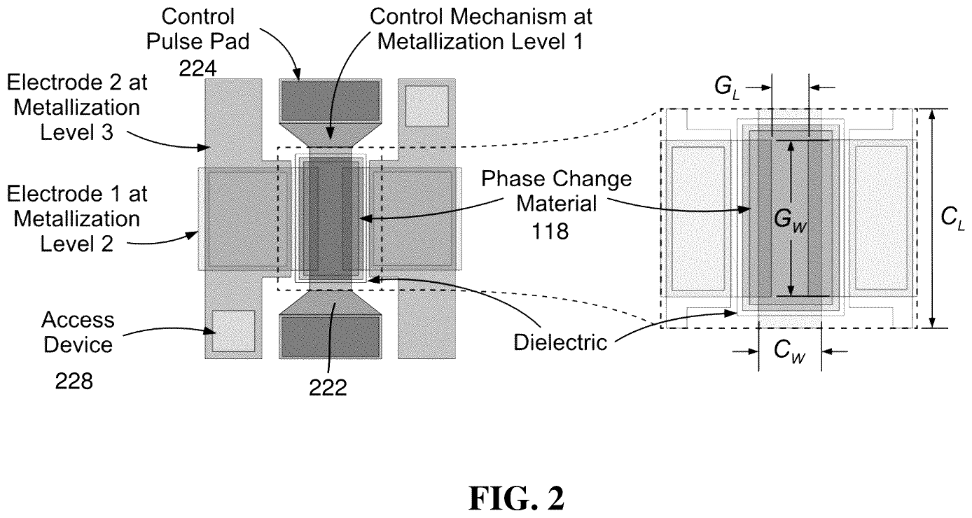

The top view of the example device 100 is shown in FIG. 2, highlighting example dimensions of various sections. The parameters G_{L} and G_{W} represent the length and width of the phase change material 118 that transitions between amorphous and crystalline states. The control circuit, or heating element 222 responsible for heating the phase change material 118 to facilitate this transitioning, has its physical dimensions indicated by C_{L} for the control circuit length and C_{W} for the control circuit width. A voltage pulse is applied to a control pulse pad 224 to heat the heating element 222 as described herein.

In general, the technology described herein reduces the inherently long write latency of phase change memory, whereby phase change memory becomes a more viable replacement for DRAM in future generations of memory systems. In one implementation, this is accomplished by doping Sb₂Te₃ with carbon and platinum, creating the compound CₓPt_{y}Sb₂Te₃, which can reduce the writing current as well as reduce the write latency, thereby addressing traditional high write latency challenges. The phase change material unit cell is based on the CₓPt_{y}Sb₂Te₃ material. Device simulations demonstrate that using appropriate ratios of each element in CₓPt_{y}Sb₂Te₃, the phase change material can effectively lower the required duration of SET pulses and improve the overall efficiency of phase change memory. It should be noted that phase change memory (PCM) is also known as phase change random access memory (PCRAM), and these terms may be used interchangeably.

Note that previous attempts to mitigate the impact of longer write latency on phase change memory performance were based on concealing the latency by scheduling SET cycles during idle bank cycles, or based on architecture-level solutions for reducing write latency in multilevel phase change memory. However, write scheduling is not suitable for high-performance systems with minimal idle cycles between memory accesses, and architecture-level solutions are specific to multilevel phase change memory, which are less favored compared to single-level cell phase change memory due to reliability and variation issues. Another technique called partial SET approach applies a short SET pulse to bring phase change memory cells to a pre-stable state, reducing the latency to that of a RESET operation; however, this technique is also not very effective as it requires an additional step to fully SET the cells later, complicating the write process.

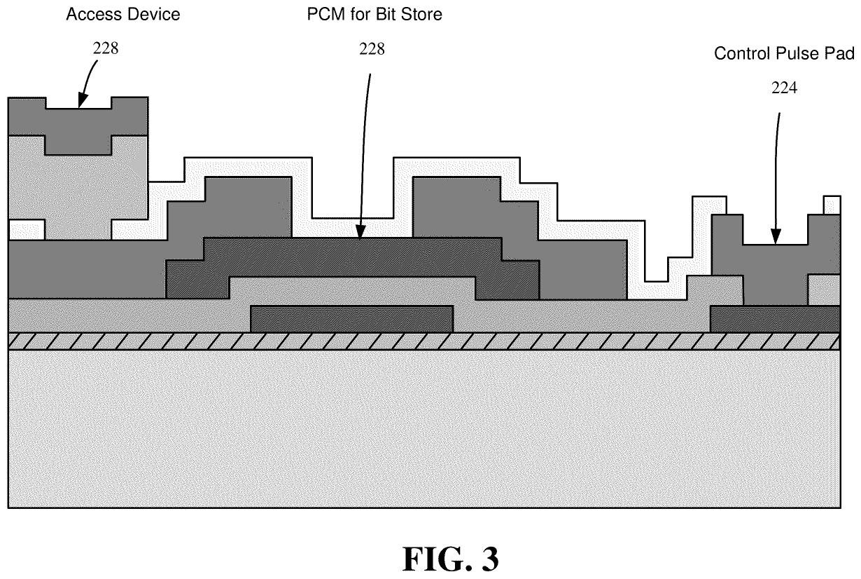

As shown in FIG. 3, components of the phase change memory unit cell include the CₓPt_{y}Sb₂Te₃ section (the phase change material that stores the bit), an access device 330, and the control pulse pad 224. The phase change material CₓPt_{y}Sb₂Te₃, where x is 15 to 20% and y is 3 to 5%, transitions between crystalline and amorphous states, exhibiting vastly different electrical resistances. The high-resistance amorphous state (in the MΩ range) represents a binary 0, while the low-resistance crystalline state (in the kΩ range), represents a binary 1. Nonnegligible current flow can be detected when in the low-resistance crystalline state, as opposed to negligible (or basically zero) current flow when in the high-resistance amorphous state. The access device 228 can be an NMOS transistor, a BJT, or a PN-junction diode. On the control pulse pad 224, the voltage pulses necessary for operation are provided. The amplitude and duration of these pulses vary for the three basic operations, namely READ, SET, and RESET.

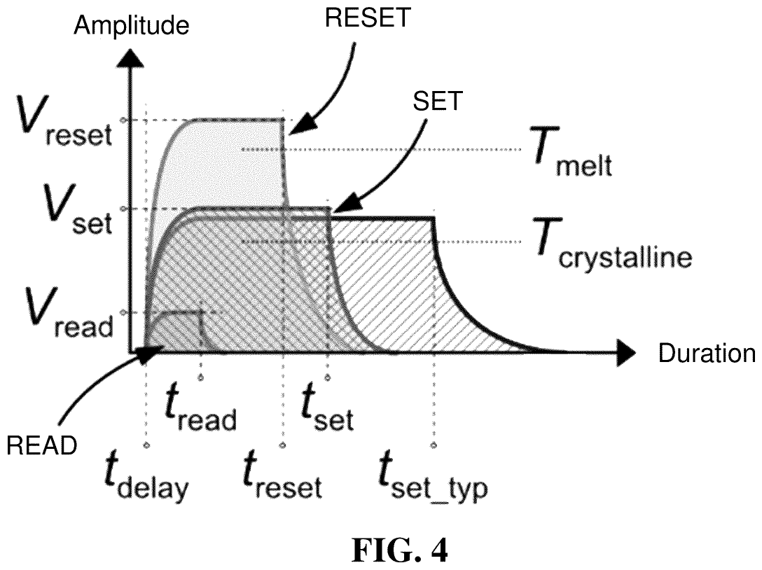

As shown in FIG. 4, a READ operation involves sending a very small amplitude (V read) pulse for short duration (tread) to sense the current flow. The significant resistance difference between the two states (0 and 1) results in large current variations, with read latency typically in tens of nanoseconds. A RESET operation applies a short, high-amplitude voltage pulse (V reset) for a tᵣₑₛₑₜ duration to melt the phase change material, which rapidly cools down to form an amorphous state, typically also in tens of nanoseconds. Conversely, a SET operation involves a longer, lower-amplitude voltage pulse (Vₛₑₜ) to transition the phase change material to a crystalline state by heating it above its crystallization temperature T_{crystalline} but below its melting point Tₘₑₗₜ. This transition typically takes hundreds of nanoseconds, shown in FIG. 4 as the typical SET time (t_{set_typical}). Instead, by doping Sb₂Te₃ with carbon and platinum, the SET pulse time (tₛₑₜ) is comparable to the RESET pulse time tᵣₑₛₑₜ, as also shown in FIG. 4. Significantly, the conductive or nonconductive state of the phase change material remains latched when the energy pulse ends, whereby the phase change material-based unit cell operates as nonvolatile memory.

As can be seen from FIG. 4, this faster-to-set phase change material addresses the primary drawback of using Ge₂Sb₂Te₅ as phase change element, namely its high write latency. From a system perspective, both SET and RESET operations frequently occur during typical phase change memory writes, where numerous bits are programmed. Hence, the average write latency in phase change memory systems is primarily dictated by the slower SET operations, making write latency significantly longer than READ latency. Using CₓSb_{y}Te_{z}, the difference between SET and RESET pulse duration is significantly reduced.

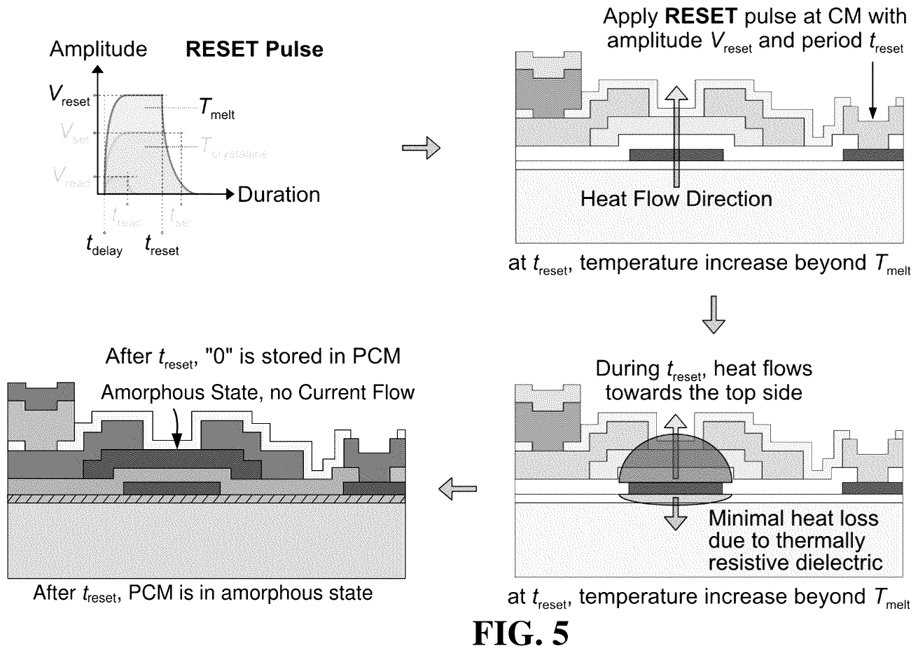

FIG. 5 shows the transition from the crystalline to the amorphous state of a PCM memory cell when a RESET pulse is applied to the control mechanism (CM), focusing on the resulting heat flow within the cell's cross-sectional stack. The RESET pulse, characterized by a high amplitude (Vᵣₑₛₑₜ) and a specific duration (tᵣₑₛₑₜ), heats the phase change material above its melting point (Tₘₑₗₜ). As the material cools, it transitions into an amorphous state, which represents a binary ‘0’. During the pulse, the heat primarily flows upwards in a dome shape due to the thermally resistive dielectric layer below, minimizing heat loss to the substrate.

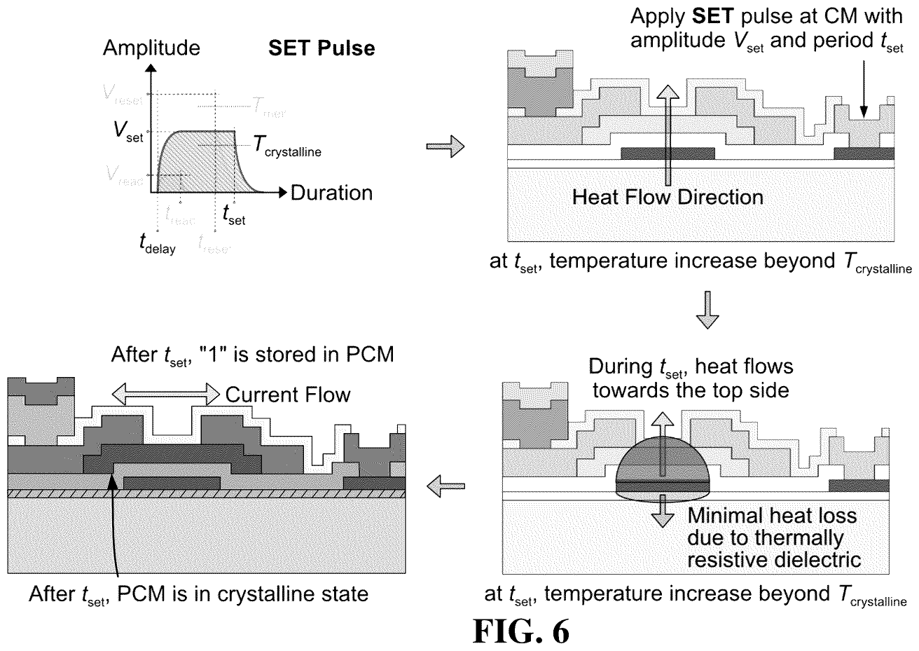

FIG. 6 shows the application of a SET pulse in a PCM cell, highlighting the heat distribution during the transition from an amorphous to crystalline state. The SET pulse, with lower amplitude (Vₛₑₜ) and extended duration (tₛₑₜ), raises the temperature of the phase change material above its crystallization threshold (T_{crystalline}) but remains below its melting point. This process results in the material crystallizing, thus encoding a binary “1”. The heat primarily flows upward, reducing heat loss to the substrate.

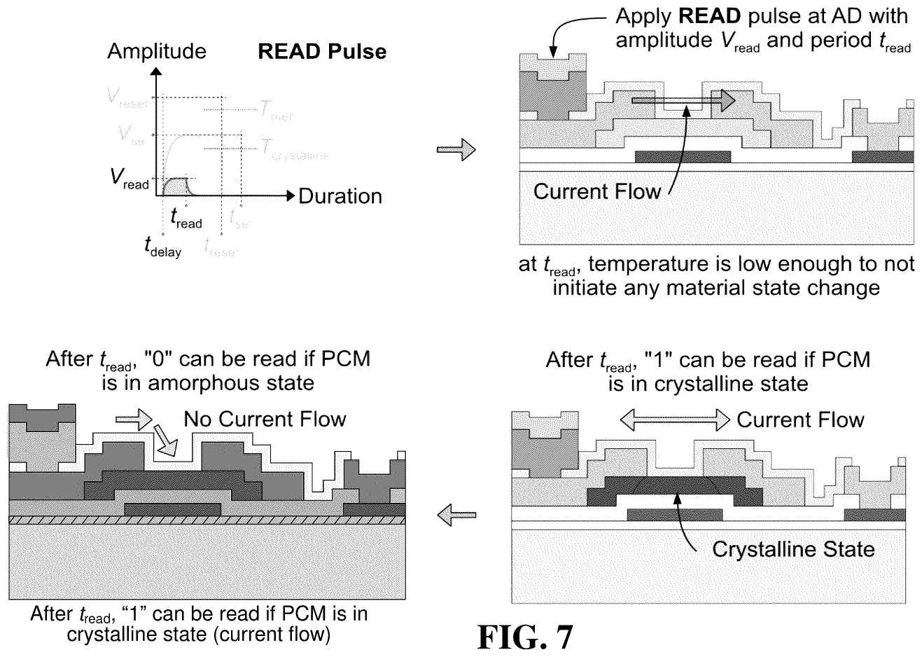

FIG. 7 shows the READ operation in a phase change memory cell. A relatively small amplitude READ pulse (V_{read}) is applied, which is sufficient to detect the current flow but not to alter the material state. Depending on whether the phase change material is in an amorphous or crystalline state, the current flow will differ. In the amorphous state, which represents a binary “0”, the high resistance prevents significant current flow. In the crystalline state, representing a binary “1”, the lower resistance allows nonnegligible current to flow, enabling the data to be read without changing the phase change material's state.

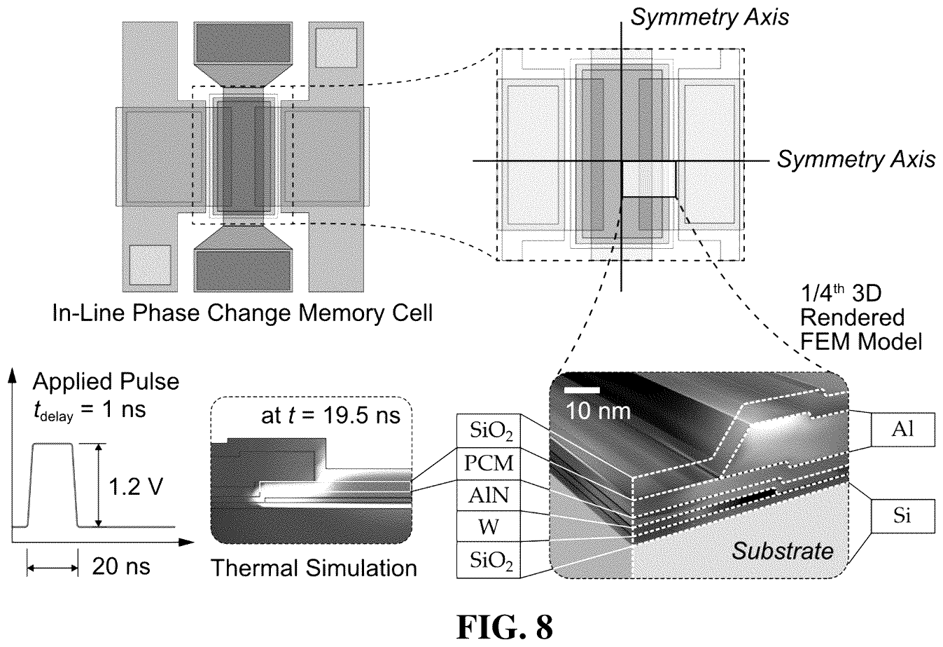

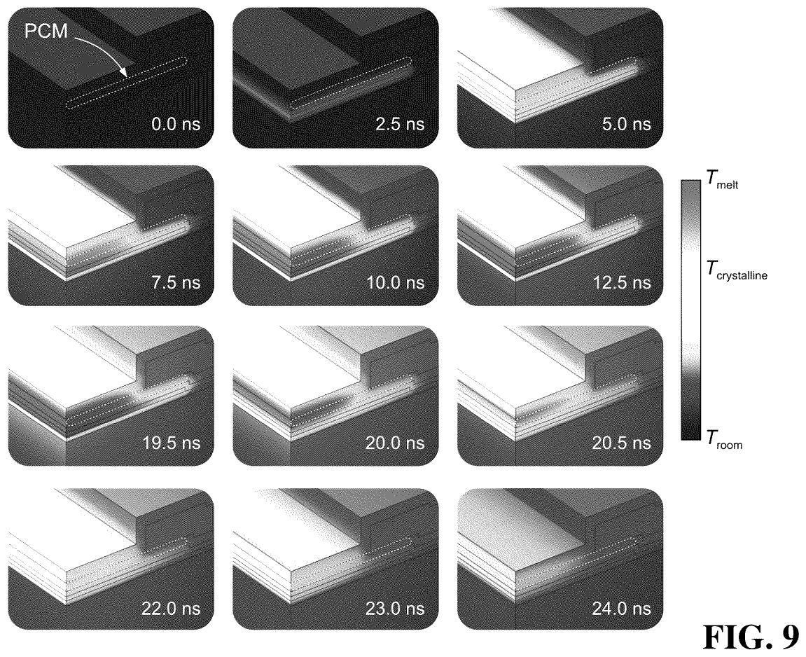

FIG. 8 shows a simulation setup for an example phase change memory unit cell. To efficiently simulate the temperature transient in the phase change memory cell, only a quarter section of the unit cell is modeled, leveraging symmetry conditions along the symmetry axes. The applied pulse has a duration of 20 nanoseconds (ns) and an amplitude of 1.2 volts (V). The top view and the 3D rendered finite element method model show the detailed structure and the areas where symmetry is applied. Thermal simulation in FIG. 9 shows how the temperature evolves in the PCM material during the applied pulse.

More particularly, the 3D full-field finite element modeler simulation shows the temperature transient in the quarter section of the symmetric phase change material in the unit cell for a duration of 24 ns. These simulations couple device physics, electric current, Joule heating, mechanical stress and strain to analyze the transient behavior. Starting from 0.0 ns, the phase change material begins at room temperature. As time progresses, the applied pulse increases the phase change material's temperature, with significant heating observed around 7.5 ns. By 10 ns, the temperature surpasses the crystallization point, continuing to rise until it reaches the peak at 19.5 ns, indicating the melting of the material. After the pulse goes down at 20 ns, the phase change material then rapidly cools, returning to near-room temperature state by 24 ns.

The doped (with carbon and platinum) phase change memory unit cell shown in FIGS. 1-3 is shown as a singular data storage element (memory cell) integrating essential components including bitlines, wordlines, and control mechanisms. Using this as a fundamental unit, a scalable array of phase change memory unit cells is designed, facilitating efficient multibit data storage and retrieval. The array's scalability makes it suitable for use in a wide range of applications, from consumer electronics to data centers.

The phase change memory array is designed to be monolithically integrated, eliminating the need for surface-mount components. Such integration is possible because phase change memory fabrication is fully compatible with advanced CMOS processes. By leveraging such processes, a phase change memory array with reduced SET times can be seamlessly integrated into larger memory architectures, enabling scalability to very large memory capacities. This approach enhances reliability while simplifying the manufacturing process, making it suitable for high-density memory applications, via a robust, scalable phase change memory architecture that fully leverages these material advancements for the continued evolution of nonvolatile memory technologies. Thus, one implementation of the phase change memory architecture as described herein features a monolithically integrated array of memory cells compatible with advanced CMOS processes. This design enhances reliability and energy efficiency by eliminating surface-mount components and enables scalable, high-density memory solutions suitable for various applications. The array structure supports efficient data storage and retrieval, while reducing the power consumption and latency typically associated with traditional phase change memory designs.

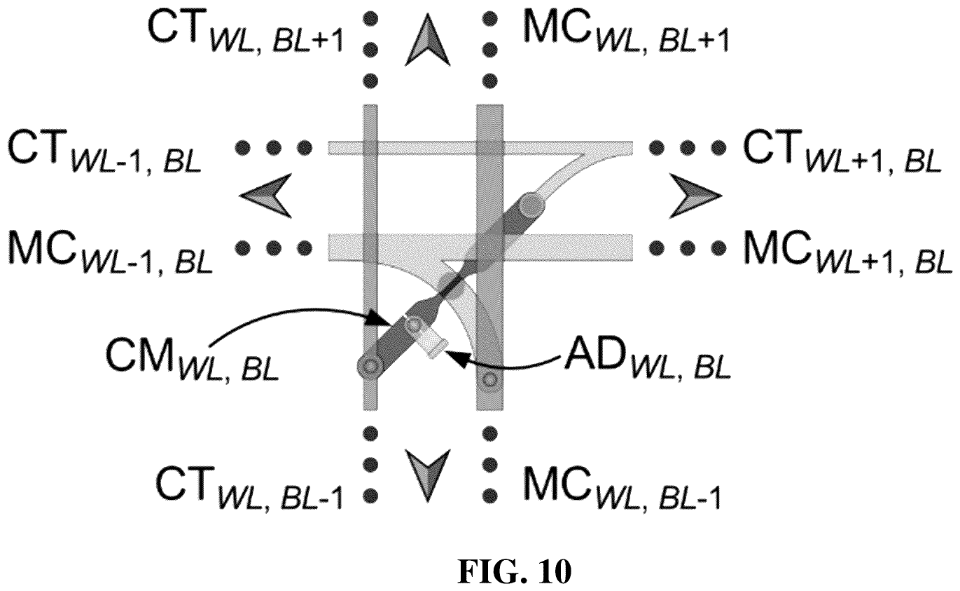

For integration into a larger array of unit cells, one example layout of the phase change memory cell is shown in FIG. 10, which highlights certain parts including control line (CT), access device (AD), control mechanism (CM), wordline (WL), and bitline (BL). A core component is the phase change material, whose state stores data (0 or 1); amorphous state means a “0”, while a crystalline state means a “1” (also it is feasible to reverse the states' meanings in some particular application). In general, a voltage to one of the wordlines turns on the access devices of an entire row, which then couples one end of each heating element and one end of each phase change material of the memory cell to ground. For each memory cell, the other end of the heating element and the other end of the phase change material are coupled to a bitline. During write operations, depending on the voltage pulse amplitude and duration as described herein, a write voltage pulse to one of the bitlines heats the heating element to “program” the phase change material to its conductive or nonconductive state. During a read operations, a read voltage pulse to the bitline of a given memory cell results in nonnegligible current flow through the phase change material when the memory cell is in its conductive state, or negligible current flow when the memory cell is in its nonconductive state, which can be sensed (e.g., by a sense amplifier coupled to a read buffer).

The control line (CT) is used to send the pulse signals to the memory cell. As set forth herein, the amplitude and duration of the pulse is different when reading, writing a “1” or writing a zero (READ, WRITE “1”, or WRITE “0”, respectively) in the memory cell. The access device (AD) manages the read and write operations, enabling access to the memory cell, via gatekeeping access to the cell. In an array of rows and columns of unit memory cells, the wordline (WL) selects which row of memory cells to activate during read or write operations. When activated, e.g., via the access device (AD), the activation enables the selection of an entire row of cells, allowing data to be read from or written to the selected row. The bitline enables the transfer of each of the individual bits of data to or from the selected row. Together, wordlines and bitlines work in coordination to access specific memory cells within an array.

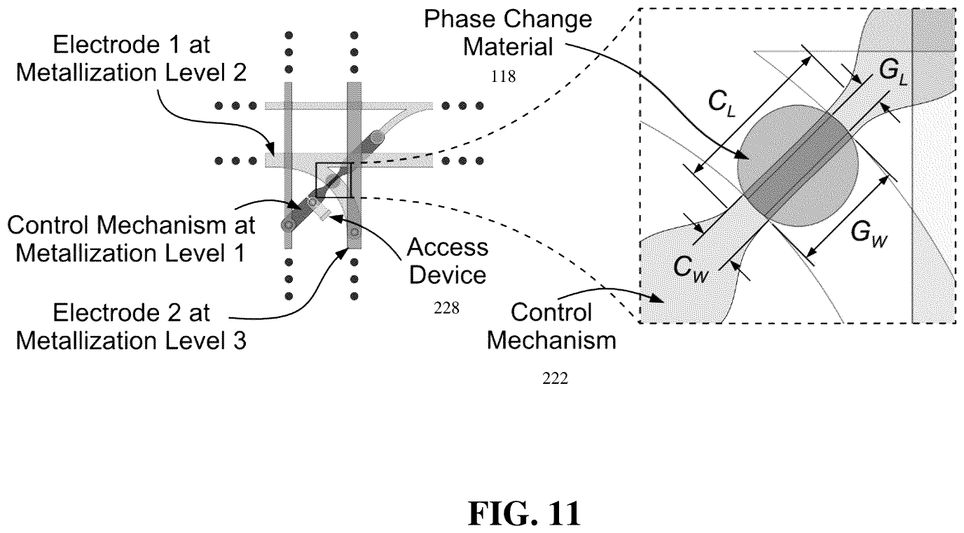

FIG. 11 shows a more detailed view of the physical structure within the phase change memory cell, showing how the example phase change material-based memory cell is structured, illustrating the complex interactions between various components that enable the storage and retrieval of data in phase change memory technology. Electrodes 1 and 2 are located at different metallization levels (Level 2 and level 3, respectively) and provide the electrical contacts to the phase change material. The control mechanism located at metallization level 1, regulates the phase change process along with the access device, by controlling the electrical and thermal inputs. The dimensions GL and GW represent the length and width of the phase change material, while CL and CW represent the length and width of the control device, that is, the heating element portion.

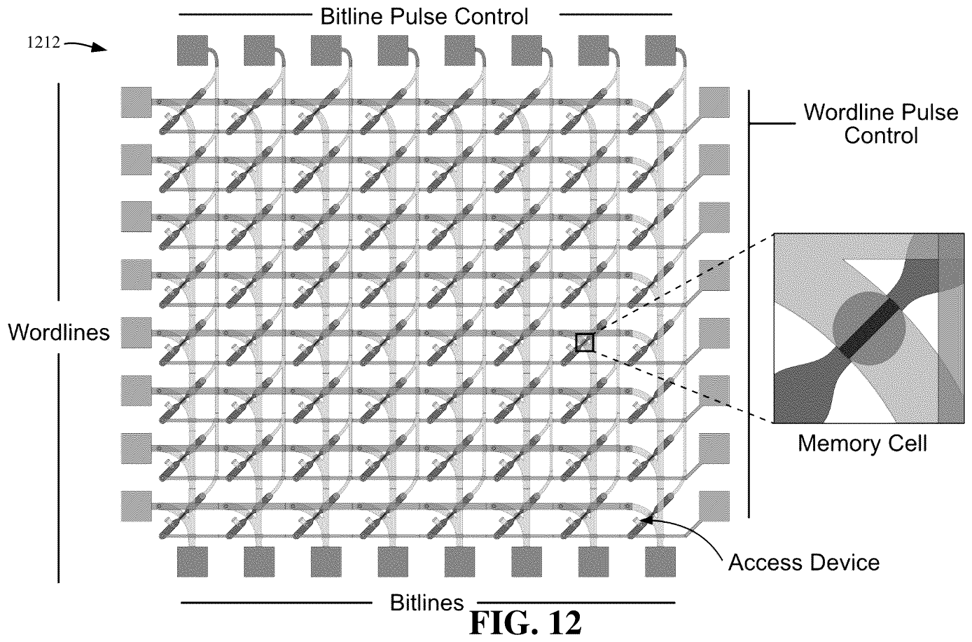

Expanding a phase change memory unit cell into a full array, as shown in FIG. 12, is a complex task based on design and integration. The array includes 1212 multiple PCM cells, which in this example is organized into an 8×8 grid, where each cell is connected via wordlines and bitlines. As is understood, this design is scalable to larger memory capacities. Writing and reading are based on precise coordination between peripheral circuitry, such as global decoders, sense amplifiers, and write drivers, to manage data read/write operations efficiently. One challenge is to ensure uniformity in cell operation, while managing crosstalk, and maintaining the integrity of the stored data across the array; such a challenge is intensified by wanting to minimize power consumption and maximize speed. Described herein is a sophisticated layout design, timing control, and the integration of various control mechanisms to handle the electrical and thermal dynamics inherent in phase change material technology.

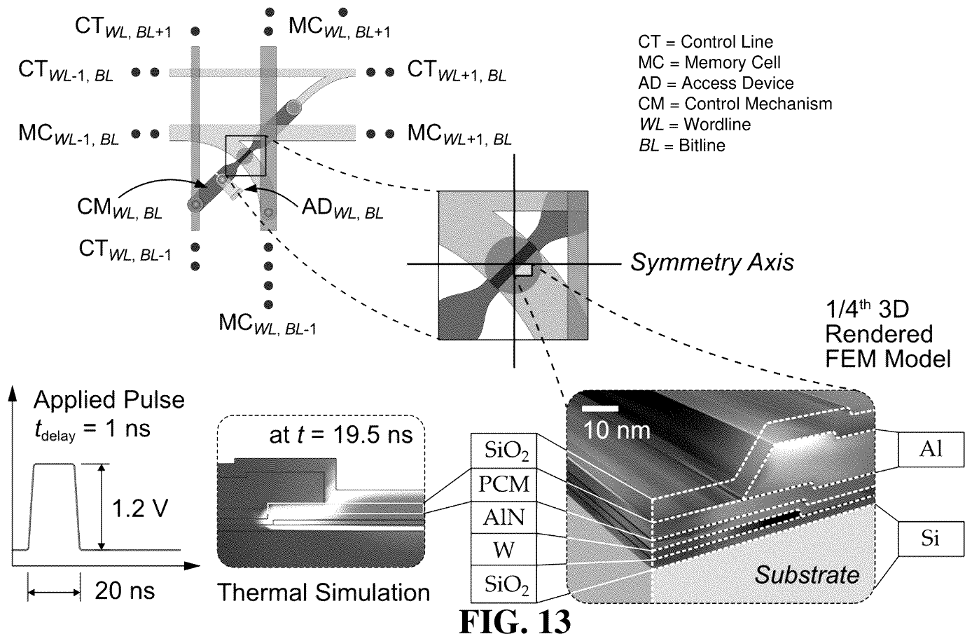

FIG. 13 provides an overview of the architecture and simulation of an example phase change memory array of unit cells. The top-left portion illustrates the layout of the example phase change memory cell. The zoomed-in section highlights the symmetry axis for the simulation. The bottom-left portion shows the thermal response of the phase change memory cell to an applied pulse, demonstrating how heat propagates through the material during a write operation. The bottom-right portion presents a 3D rendered finite element model (FEM) simulation of the phase change memory cell, visualizing the temperature distribution and the physical structure at the nanoscale; this portion also highlights the multiple metallization and dielectric layers, along with identifying some (nonlimiting) suitable materials, e.g., “W” represents the tungsten heating element.

Turning to one significant usage of phase change material-based memory arrays, convolutional neural networks (CNNs) are powerful neural networks in artificial intelligence (AI) and machine learning (ML) applications, often used with images for identifying objects, scenes, and/or activities within the images. However, CNNs encounter significant computational and memory challenges due to the heavy demands of the Multiply-and-Accumulate (MAC) operations used in the applications. Traditional processor-centric architectures struggle with increasing dataset sizes, leading to higher latency and energy consumption.

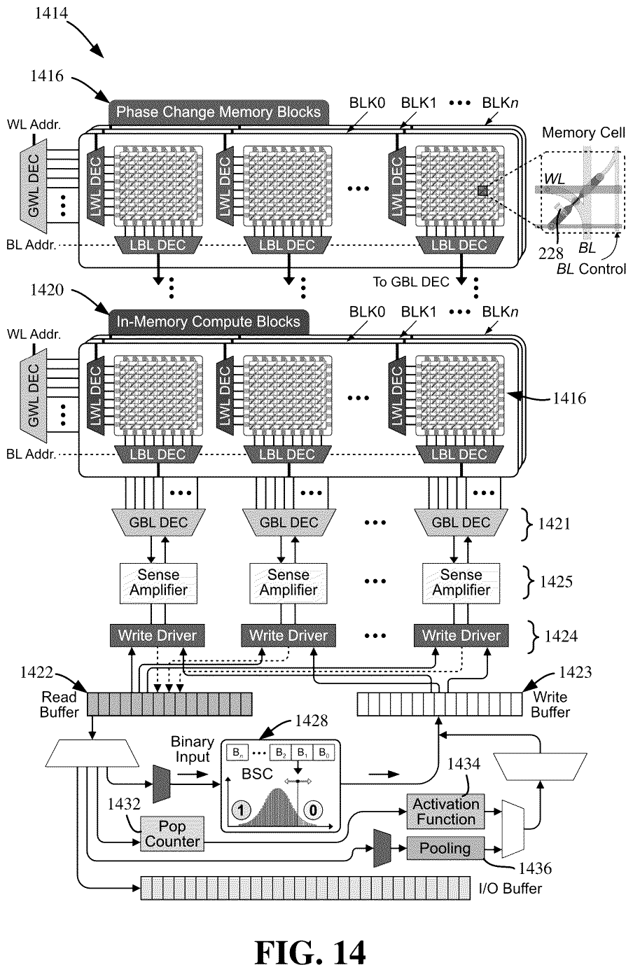

The technology described herein facilitates “Processing-in-Memory” (PIM), which brings processing units closer to memory, reducing data transfer bottlenecks. FIG. 14 shows an example architecture/system 1414 for a nonvolatile phase-change memory with in-memory computation using stochastic arithmetic. In general, the system 1414 speeds up convolutional neural networks (CNNs) for at least two reasons. First, calculations are moved directly into memory; instead of constantly transferring data between memory and processors, which takes time and uses extra power, the system 1414 does the work within the memory. This approach, thus leverages processing-in-memory concepts to make CNN operations faster, generally because data does not have to travel back and forth between the memory and the processor, with processing occurring in parallel where the data is stored.

Note that such a type of architecture can be successfully achieved in very few advanced memory technologies; by leveraging phase change materials as described herein, the phase change memory architecture utilizes phase change memory, where the phase change memory arrays are split into storage and computational areas. In this way, many operations can be handled at once, which is appropriate for the repeated calculations that CNNs rely on to process images, videos, or other large datasets.

Another reason why the example architecture/system 1414 speeds up CNNs is the use of stochastic arithmetic for many of the calculations in CNNs, which are multiply-and-accumulate (MAC) operations. Stochastic representation refers to having values represented by bit streams (a series of 0s and 1s), where the probability of a bit being “1” correlates to the value it represents. Stochastic arithmetic simplifies multiply-and-accumulate operations by converting complex multiplications and additions into basic logical operations like AND gates (for multiplication) and multiplexing (for addition). This reduces the hardware complexity and is beneficial in CNNs that deal with repeated MAC operations across large datasets. Note however that because stochastic computation relies on probabilistic bit streams, stochastic computation may introduce some accuracy loss, and although the more bits in the stream the closer the result approximates the exact value, the result is still an approximation. For CNN applications, some level of approximation is often acceptable, such as when the overall gain in speed outweighs the minor loss in precision. CNNs can tolerate slight variations in computation, particularly in large models where rounding or small approximations have limited effect on overall model performance.

Typically, the most common drawback of using stochastic arithmetic for multiply-and-accumulate operations is not the sacrifice in accuracy, but rather the additional add-on circuitry needed for binary-to-stochastic conversion (BSC) every time. The technology described herein resolves this drawback by having the binary-to-stochastic conversion embedded in the memory cells, with conversion based on the inherent properties of phase change material.

As shown in FIG. 14, the example phase change memory architecture divides the memory arrays into (e.g., one of which is labeled 1416) into two partitions, namely one partition 1418 (the phase change memory blocks) for storing the data and another partition 1420 (the in-memory compute blocks) for in-memory computation. The benefits of this approach include reducing the need for excessive data transfers by integrating processing units directly within memory, and using stochastic arithmetic for enhancing the efficiency and speed of CNNs. Additionally, the hardware architecture 1414 can be seamlessly integrated with heterogenous computing systems, with only lightweight modifications to phase change memory peripherals and the inclusion of add-on logic in memory banks for in-situ processing of CNNs, making the technology described herein a suitable processing-in-memory architecture.

In the example of FIG. 14, the phase change memory cells are organized into hierarchical blocks and sub-blocks, with peripheral circuits including global decoders 1421, read buffers 1422 and write buffers 1423, write drivers (WDs) 1424, and sense amplifiers (SAs) 1425 shared among these blocks and multiplexed across sub-blocks. During operations, global and local bitline decoders (GBL DEC and LBL DEC) and global and local wordline decoders (GWL DEC and LWL DEC) select, based on a binary bitline address and binary wordline address, respectively, the specific rows and cells, connecting them to the sense amplifiers 1425 for reading, or to the write drivers 1424 for writing. WRITE operations involve current flowing from the write drivers 1424 through the bitlines, the phase change material, and the access device (e.g., 228) to the cell's ground. READ operations follow a similar path, with current originating from the sense amplifiers 1425. Each phase change memory chip includes dedicated charge pumps (CPs) to supply the appropriate voltage and current amplitudes for READ, RESET, and SET operations, with multiunit charge pumps managing the different current levels for these processes.

The architecture 1414 in FIG. 14 includes a partition 1420 within each phase change memory bank as a computational space, such as for in-situ CNN processing. This space, termed the compute partition 1420, facilitates the execution of multiply-and-accumulate operations using stochastic arithmetic directly within the phase change memory banks. Modifications are made to phase change memory bank peripherals, including the sense amplifiers 1425, row-address decoders, and wordline drivers, to enable efficient in-situ processing. These modifications allow for the simultaneous activation of two phase change memory rows, enabling bit-parallel logical operations appropriate for stochastic arithmetic.

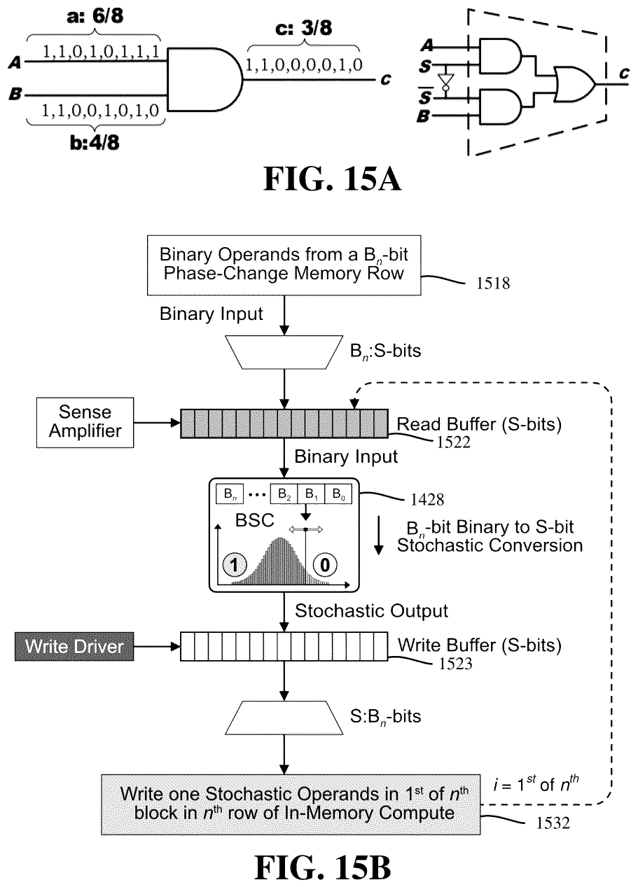

For CNNs, the use of stochastic arithmetic for multiply-and-accumulate operations reduces the complexity and size of the hardware used for multiply-and-accumulate operations by converting complex arithmetic operations into simpler logical operations. In practice, multiplication within the stochastic format can be achieved using simple bit-parallel AND operations, while scaled addition (accumulate) is performed through a bit-parallel multiplexing (MUX) operation. The left portion of FIG. 15A shows an AND gate implementing c=a×b in the stochastic number format, and the right portion of FIG. 15B shows a MUX adder circuit implementing c=s×a+s′×b in the stochastic number format; a value of s=0.5 can be used for MUX-based stochastic addition, for example.

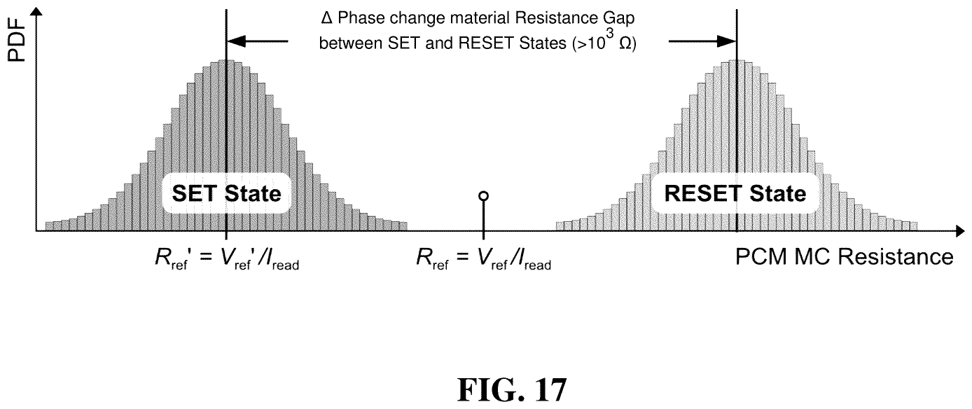

This is exemplified in the phase change memory architecture 1414 (FIG. 14) where the binary input is converted into a stochastic number, processed through logical operations, and then converted back to binary as needed. However, typical stochastic computing has to have additional circuits for converting operands between binary and stochastic formats, which can be costly in terms of area and power, which is a significant bottleneck. The technology described herein includes leveraging a phase change memory-based binary-to-stochastic converter, e.g., as described herein with reference to FIGS. 17-19, which in one implementation is integrated directly into the memory architecture (BSC block 1428 of FIG. 14) to minimize area and power overheads. The binary-to-stochastic converter 1428 transforms CNN multiply-and-accumulate operands from binary to stochastic format on-demand, reducing the need for pre-converted stochastic operands that would otherwise have to have impractically large storage capacities.

Turning to an example operation, FIG. 15B depicts an example process flow sequence for converting CNN operands from binary to stochastic format and storing them into the compute partition with the phase change memory architecture. The example sequence begins (block 1518) with reading binary operands from a phase change memory row into a read buffer (block 1522). These operands are then converted into stochastic format (block 1428) and subsequently written back (from a write buffer 1523) into designated phase change memory rows within the compute partition (block 1532). The conversion is done by the example in-situ phase change memory-based binary-to-stochastic converter (block 1428) described herein. For example, a 9×256-bit phase change memory block read from an 8 Kb phase change memory row can retrieve 32 8-bit operands. These are each converted into 32 stochastic operands, 256-bit each, and stored in 32 separate rows of the compute partition 1420 in the phase change memory architecture 1414 (FIG. 14).

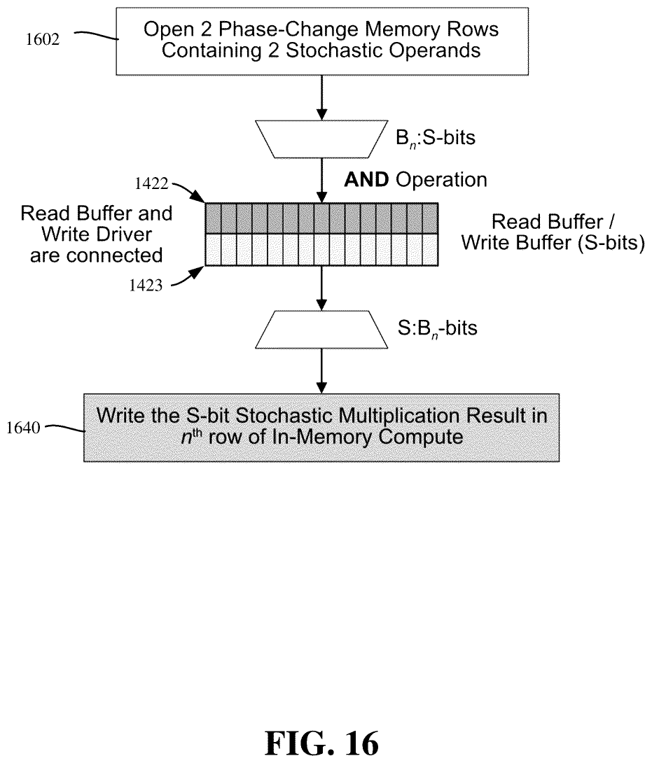

Turning to another example operation, FIG. 16 depicts an example command flow sequence for performing a (bit-parallel AND) multiplication operation between two stochastic (e.g., CNN) operands stored in the stochastic format (e.g., 256-bit each) in separate phase change memory rows within the compute partition 1420 of FIG. 14. The example operation involves simultaneously activating (block 1602) the phase change memory rows and reading the operands using a reference voltage in the sense amplifiers. This process executes a bit-parallel AND between the two 256-bit stochastic operands, producing the result directly in the phase change memory's compute partition (block 1640). A pop counter 1432 (FIG. 14) is used in the architecture 1414 for converting stochastic operands back into binary format. The pop counter 1432 works in conjunction with a clocked 256-bit parallel-in-serial-out register and an 8-bit digital level counter to efficiently manage and process stochastic operands.

For the activation function (block 1434) and pooling function (block 1434), in one implementation binary arithmetic logic can be used. For the activation function (block 1434), a CMOS implementation of an 8-bit ReLU (Rectified Linear Unit) function can be used. ReLU is one of the more popular activation functions in CNNs and it is defined as:

ReLU(x)=max(0,x)

The output of the ReLU function is [0, ∞]. ReLU introduces non-linearity into the model, which helps the network learn complex patterns. It is computationally efficient because it only involves a simple thresholding at zero. Implementing the ReLU function in CMOS technology involves designing an analog circuit that can efficiently realize the ReLU operation, i.e., outputting zero for negative inputs and passing positive inputs unchanged, typically done using NMOS and PMOS transistors.

Pooling functions (block 1434) are used in CNNs to reduce the spatial dimensions (width and height) of the input volume. This down-sampling operation helps in reducing the number of parameters and computations in the network, which also helps to control overfitting. Pooling layers are typically inserted between successive convolutional layers. One example implementation uses max pooling in the architecture 1414, which takes the maximum value from each patch of the feature map to capture the most prominent (highest activation) in each region. A 4:1 max pooling function is used; the 4:1 aspect means that the pooling operation reduces the spatial dimensions by a factor of 4. For each 2×2 (as 2*2=4) window in the input feature map, the maximum value is selected and output to form a down-sampled feature map. This can be achieved in a software (e.g., using Python) implementation, while its hardware (e.g., CMOS) implementation involves using comparators and multiplexers to achieve the same functionality in hardware, providing a foundation for building integrated memory architectures.

To summarize, in conventional systems, CNNs face significant challenges due to the memory bottleneck when accessing numerous operands, which limits their acceleration. Existing crossbar memory-based processing-in-memory accelerators, which use analog computing, suffer from inefficiencies due to power-intensive digital-to-analog converters (DACs) and analog-to-digital converters (ADCs) and still depend on processor-centric methods for significant functions. The phase change memory technology described herein provides a straightforward, low-overhead, and energy-efficient in-memory compute architecture that exploits the advantages of processing in-memory for CNN processing, eliminating the reliance on traditional processing units and reducing the energy and latency overhead associated with data transfers. More particularly, the architecture of FIG. 14 integrates phase change memory for in-memory computing to overcome the limitations of traditional CNN processing; by dividing phase change memory into storage and compute partitions, the architecture reduces data transfer overhead and improves efficiency using stochastic arithmetic for multiply-and-accumulate operations. The architecture can include modifications to peripherals for in-situ operations, and can employ a binary-to-stochastic converter to manage operand formats. Binary arithmetic is retained for activation and pooling functions, ensuring a balance between efficiency and performance.

The example architecture 1414 divides phase change memory into distinct storage and compute partitions, optimizing data handling and reducing the need for data transfer between memory and processing units. The example architecture 1414 can include modifications to phase change memory peripherals such as sense amplifiers, row-address decoders, and wordline drivers to support in-situ processing, enabling efficient execution of multiply-and-accumulate operations directly within the memory. A hybrid arithmetic approach also provides benefits. By combining stochastic arithmetic for multiply-and-accumulate operations with traditional binary arithmetic for activation and pooling, the architecture maximizes computational efficiency while minimizing hardware overhead, offering a versatile and energy-efficient solution for CNN acceleration.

Turning to a binary-to-stochastic converter based on leveraging multi-state resistance change in phase-change materials, as set forth herein phase change memory (phase change memory) cells can be programmed to have different resistance states (high or low), representing binary values “0” and “1”. The binary-to-stochastic conversion operates by adjusting the reference voltage used to read these states, by which the system can generate stochastic numbers directly in memory. When reading a row of phase change memory cells, only a controlled percentage of cells appears as “1s” based on this reference voltage, creating a probabilistic or stochastic representation of the binary numbers. This saves space and power, as no additional hardware is needed for conversion, which benefits power-sensitive devices, like those used in edge AI, by improving processing speed while reducing energy use.

The phase change memory architecture 1414 of FIG. 14 is capable of performing in-memory multiply-and-accumulate operations using stochastic arithmetic with little additional logic. Stochastic computing, which utilizes pseudo-random numbers for arithmetic operations, can significantly reduce the hardware devices for multiply-and-accumulate operations, enhancing both energy efficiency and processing speed in CNNs. This provides a more efficient alternative to traditional binary computation. However, stochastic computing relies on random bit streams, which when generated by conventional binary-to-stochastic converter s, tends to be area-intensive and energy-intensive. Additionally, the numerical precision of conventional binary-to-stochastic converters rely on enhancement to reduce errors in stochastic computations. Such challenges can offset the benefits of stochastic computing in processing-in-memory architectures.

The technology described herein includes a binary-to-stochastic converter design that leverages the inherent stochastic nature of phase change material used in phase change memory. The binary-to-stochastic converter, described herein with reference to FIGS. 17-19, is highly scalable with a minimal hardware footprint, offering a promising solution for efficient stochastic computing in processing-in-memory architectures.

Note that typically, linear feedback shift registers (L FSRs) are used for generating pseudo-random numbers while converting binary numbers to stochastic numbers in various computational applications. However, when applied within in-memory processing architectures, whether with dynamic random access memory (DRAM) or even phase change memory as described herein, LFSRs present several disadvantages. First, L FSRs need a significant amount of additional hardware, which increases the overall complexity and footprint of the memory system. Such hardware overhead can lead to higher energy consumption and reduced efficiency, particularly in large-scale applications. Furthermore, LFSRs are limited in their scalability; as the demand for processing larger datasets grows, the inefficiencies of LFSRs become more pronounced, resulting in suboptimal performance for in-memory computing tasks. These limitations hinder the potential advantages of phase change memory architectures, which are designed to minimize data transfer distances and leverage high internal memory bandwidth.

To address these challenges, as described herein, a phase change memory-based binary-to-stochastic converter is used, which integrates the binary-to-stochastic converter 1428 directly within the phase change memory architecture 1414 (FIG. 14), significantly reducing hardware complexity and energy consumption. By leveraging the inherent properties of phase change memory, the binary-to-stochastic converter 1428 results in improved scalability and performance, making it a more suitable solution for in-memory processing tasks. The phase change memory-based binary-to-stochastic converter 1428 facilitates efficient stochastic computing, thereby enhancing the overall capabilities and efficiency of phase change memory architectures.

More particularly, the binary-to-stochastic converter 1428 integrated with the phase change memory architecture 1414 addresses challenges related to computational and memory demands, including with CNNs. The phase change memory-based binary-to-stochastic converter 1428 leverages the inherent stochastic properties of phase change memory cells to generate stochastic bit-vectors, enhancing energy efficiency and processing speed. The system reduces hardware complexity by replacing traditional linear feedback shift registers with a phase change memory-based reference voltage generator, resulting in improved scalability and performance in in-memory processing.

FIG. 17 is a graphical representation of the resistance difference between SET (crystalline) and RESET (amorphous) states in a phase change memory cell, showing a significant gap used to represent binary data. As set forth herein, a phase change memory cell contains a small volume of chalcogenide material, which can be “programmed” into two distinct states, namely a crystalline (SET) and amorphous (RESET) state, each with significantly different electrical resistance. The resistance difference between the two states is in the order of 103 (2. The amorphous (RESET) state represents a binary “0”, while the crystalline (SET) state represents a “1”. The resistance of phase change memory cells in the SET state (R_{SET}) follows a normal distribution (probability density function (PDF)) in the kΩ range, whereas the resistance of phase change memory cells in the RESET state (R_{RESET}) follows a normal distribution in the MΩ range, as shown in FIG. 17.

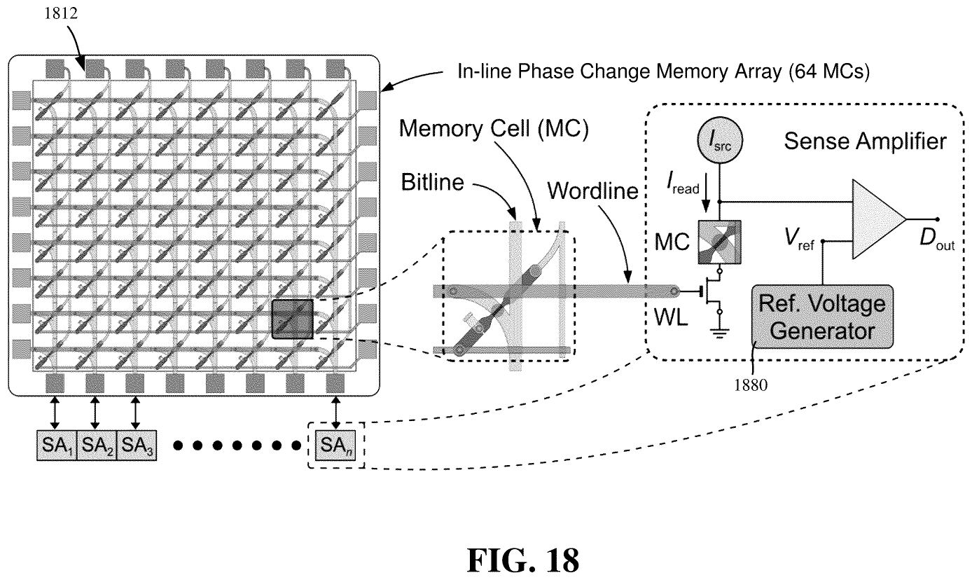

FIG. 18 shows a phase change memory cell array 1812 with shared sense amplifiers (SA₁-SAₙ) that read stored data by comparing voltage drops across the cells against a reference voltage (V_{REF}). As shown in FIG. 18, the rows of phase change memory cells share sense amplifiers (SAs). To read data from a phase change memory row, a read current pulse I_{READ} is applied to each phase change memory cell (to one end of the phase change material therein) from a source I_{src}; the other end of the phase change material is grounded via the activated access device (a transistor in this example) when the wordline is activated. This current generates a voltage drop across the cell, which varies depending on whether the cell is in the SET or RESET state (V_{SET}=R_{SET}×I_{READ} or V_{RESET}=R_{RESET}×I_{READ}). Each sense amplifier (e.g., SAₙ) compares this voltage drop against a reference voltage (V REF) (obtained from a reference voltage generator 1880) to determine the stored value. If V_{SET}<V_{REF}, the cell is read as a ‘1’; if V_{RESET}>V_{REF}, the cell is read as a ‘0’.

For a phase change memory array, I_{READ} and V_{REF} can be designed so that V_{REF}/I_{READ} falls in the middle of the resistance distributions of SET and RESET cells shown in FIG. 17. As a result, for a phase change memory row being read, V_{SET} for the SET cells is less than V_{REF}, whereas V_{RESET} for the RESET cells is greater than V_{REF}, enabling the distinction of the SET cells (logic ‘1’s) from the RESET cells (logic ‘0’s) with virtually one-hundred percent probability.

By way of example, consider a phase change memory row where all its cells are preprogrammed in the SET state (‘1’s). For this read operation, with V_{REF} controlled such that V_{REF}/I_{READ} falls somewhere on the resistance distribution of the SET cells, the number of cells that would be read as ‘1’s is controllable. For instance, if V_{REF} is adjusted to a value V_{REF}′ that places V_{REF}′/I_{READ} at the center of the resistance distribution for SET cells as highlighted in FIG. 17, only half of the cells in the SET phase change memory row would be read as ‘1’s (as these cells fall on the left of the V_{REF}′/I_{READ} reference), the remaining half of the cells would be read as ‘0’s.

The ability to control the read operation forms the basis for designing an efficient binary-to-stochastic converter. By appropriately adjusting V_{REF} during the read process, the inherent properties of phase change memory cells are leveraged to generate stochastic numbers, enhancing the efficiency of in-memory processing.

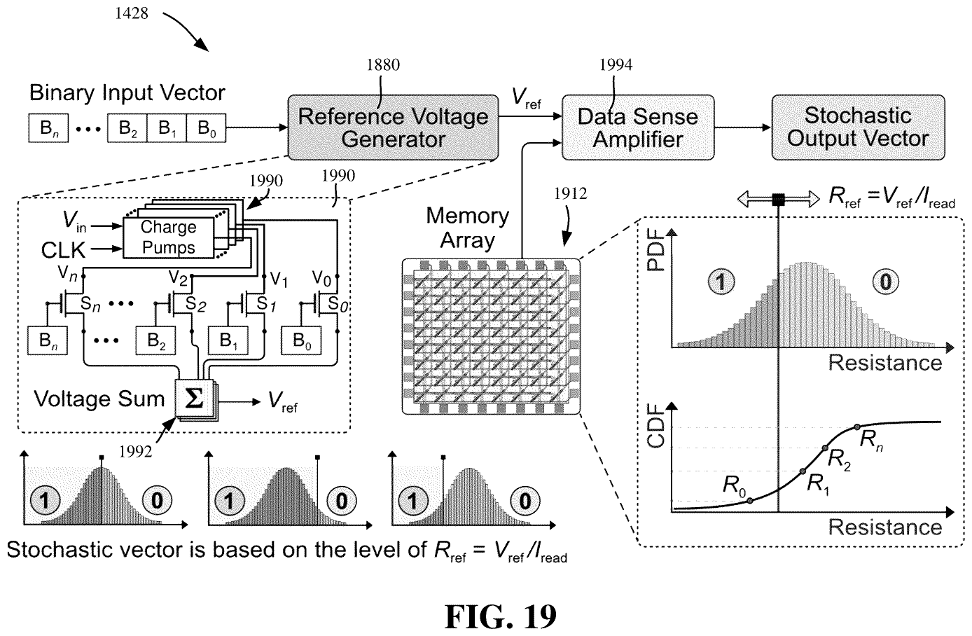

FIG. 19 represents a functional block diagram of the phase change memory-based binary-to-stochastic converter 1428. To convert an N-bit binary input number into a 2-bit stochastic bit-vector, the binary-to-stochastic converter 1428 utilizes the phase change memory-based reference voltage generator 1880 to generate the reference voltage V_{REF} needed for reading a row of 2^{N} phase change memory cells.

The zoomed-in section demonstrates the operation of reference voltage generator 1880 for any N-bit binary input (B_{N-1} . . . . B₁B₀). The N-bit reference voltage generator 1880 contains N numbers of CMOS switches (S₀ to S_{N-1}), each corresponding to a bit (B₀ to B_{N-1}) in the N-bit binary input number (Bₙ to B₀). Depending on the value of each bit (‘0’ or ‘1’) provided to the switch gate, the respective switch connects (if turned on by a bit equal to ‘1’) its corresponding voltage source (Vₙ to V₀, implemented using a corresponding one of the respective charge pumps 1990) to the voltage summer circuit 1992. The output of the voltage summer circuit 1192 is V_{REF}. Note that from most significant bit to least significant bit, each voltage from a charge pump is double the voltage of that of the next bit.

A simulated probability distribution function (PDF) and cumulative distribution function (CDF) for the resistance of phase change memory SET cells is shown in the graphical representation on the right side of FIG. 19. Therefore, the voltage level V_{X} of the voltage source corresponding to a bit B_{X} from the N-bit input can be calculated as:

V_{X}=I_{READ}×CDF⁻¹(2^{X}/2^{N}),

where CDF⁻¹( ) is the inverse CDF function that provides the resistance value R_{X} for a given probability number. Consequently, the N-bit reference voltage generator 1880 produces V_{REF} as:

$${V}_{REF} = {\sum }_{X = 0}^{N - 1} {B}_{X} {V}_{X} ,$$

using the embedded voltage summer circuit 1992. When this V_{REF} is applied to read a row with 2^{N} SET phase change memory cells, only the

$$( {\sum }_{X = 0}^{N - 1} {B}_{X} {2}^{X} )$$

number or cells out of total 2^{N} cells are read as ‘1’s, and the remaining cells are read as ‘0’s, thereby converting an N-bit input into a 2^{N}-bit stochastic output.

For example, if the input 3-bit binary number is 110 (i.e., B₂=1, B₁=1, B₀=0), an 8-bit vector with six ‘1’s and two ‘0’s should be produced. In this case, the voltage level V₂ of the voltage source for the bit B₂=1, can be determined as:

V₂=I_{READ}×CDF⁻¹(2²/2³)=I_{READ}×CDF⁻¹(4/8).

Similarly, V₁ and V₀ can be calculated:

V₁=I_{READ}×CDF⁻¹(2¹/2³)=I_{READ}×CDF⁻¹(2/8).

V₀=I_{READ}×CDF⁻¹(2⁰/2³)=I_{READ}×CDF⁻¹(1/8).

Consequently, V_{REF} is generated as:

V_{REF}=B₀V₀+B₁V₁+B₂V₂=V₁+V₂,

as B₀ is zero for the example number 110, whereby the switch S₀ is not turned on whereby V₀ is not input to the voltage summer circuit 1992. This V_{REF} is used to read (via data sense amplifier 1994) a total of 2³=8 phase change memory SET cells, which are all preprogrammed to their SET states, e.g., in the rows of the in-memory compute blocks in the memory array 1912 where the stochastic vector will be written as determined. If instead the binary input vector was an eight-bit operand, 256 SET cells are read using the V_{REF} voltage computed from the eight zero or one bits of the of the eight-bit operand as the binary input vector. Note that the higher the V_{REF} voltage, the more “ones” are sensed, whereas the lower the V_{REF} voltage, the more “zeros” are sensed. The stochastic behavior arises during the sensed read operation because of the natural cell-level resistance variation and position of V_{REF} on the resistance CDF (the lower right corner of FIG. 19).

Note that each of the SET states has a different resistance, in a distribution pattern as shown in the lower right portion of FIG. 19, whereby the V_{REF} voltage, which is between the ends of the distribution, results in the data sense amplifier 1994 reading some of the SET cells as zero (even though they would be considered “SET” in the conventional sense). The binary input vector determines how many are sensed as ones and how many are sensed as zero, with the more significant bits having more weight in the summed voltage than the less significant bits. As a result, in the above example B₀2⁰+B₁2¹+B₂2²=2¹+2²=2+4=6 cells are read as ‘1’s, and the remaining 2 cells are read as ‘0’s, thus accurately converting the binary input 110 into an 8-bit stochastic number.

The integration of a binary of stochastic converter directly within the phase change memory architecture eliminates the need for additional complex hardware like linear shift feedback registers. This reduces energy consumption and hardware complexity. By generating a reference voltage for sense amplifiers based on the resistance distribution of phase change memory cells, efficient conversion of binary inputs into stochastic outputs is accomplished in a way that is tailored for high precision and scalability. As a result, in-memory multiply-and-accumulate operations are achieved with minimal additional logic by leveraging the inherent stochastic properties of phase change memory cells.

One or more implementations can be embodied in a storage device. The storage device can include a memory cell, including a phase change material, and a heating element controllable to transfer first heat via a set pulse to the phase change material to transition the phase change material into a conductive state, in which a read voltage pulse applied to the phase change material results in a nonnegligible current flow, through the phase change material, that corresponds to a first bit value, or transfer second heat via a reset pulse to the phase change material to transition the phase change material into a nonconductive state, in which the read voltage pulse applied to the phase change material results in a negligible current flow, through the phase change material, that corresponds to a second bit value that is different from the first bit value. The phase change material can include a first amount of a phase change alloy doped with a second amount of carbon and a third amount of platinum, to result in the phase change material transitioning to the conductive state via the set pulse with a shorter set pulse duration, relative to a longer set pulse duration used to transition a corresponding phase change alloy that is not doped, to a corresponding conductive state.

The first amount of the phase change alloy can include an amount of antimony telluride, and wherein the second amount of the carbon can include between about twelve to twenty-five percent of the amount of the antimony telluride.

The first amount of the phase change alloy can include an amount of antimony telluride, and wherein the third amount of the platinum can include between about two to six percent of the amount of the antimony telluride.

The first amount of the phase change alloy can include an amount of antimony telluride, wherein the second amount of the carbon can include between about twelve to twenty-five percent of the amount of the antimony telluride, and wherein the third amount of the platinum can include between about two to six percent of the amount of the antimony telluride.

The first bit value can be a one bit value, and the second bit value can be a zero bit value.

The memory cell can include a substrate, and the device can include a thermally resistive dielectric material between the heating element and the substrate.

The memory cell can include a thermally conductive dielectric material between the heating element and the phase change material.

The memory cell can include a bitline and a wordline, the heating element can be coupled to the bitline, the phase change material can be coupled to the bitline, and an access device can be coupled to the wordline to activate the memory cell to facilitate current flow through the phase change material and the access device.

When activated by the access device, in the conductive state of the phase change material, the read voltage pulse can result in the nonnegligible current flow through the phase change material that corresponds to the first bit value, and in the nonconductive state of the phase change material, the read voltage pulse can result in the negligible current flow through the phase change material that corresponds to the second bit value.

The phase change material junction can remain latched in the conductive state or the nonconductive state following completion of the set pulse or the reset pulse, respectively, until the heating element can be controlled to transfer third heat to the phase change material junction via a next set pulse, or transfer fourth heat to the phase change material junction via a next reset pulse.

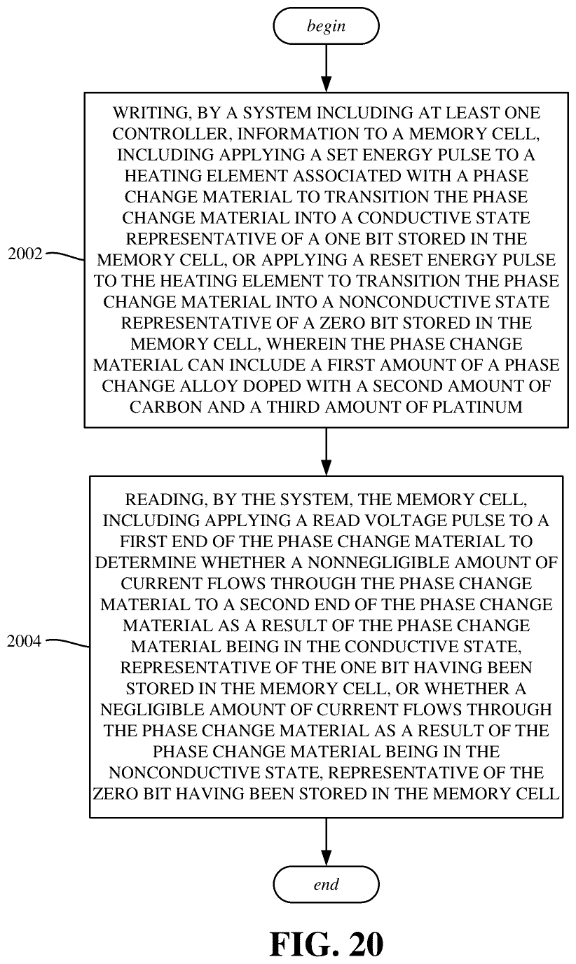

One or more example embodiments, implementations, and/or operations, such as corresponding to example operations of a method, can be represented in FIG. 20. Example operation 2002 represents writing, by a system including at least one controller, information to a memory cell, including applying a set energy pulse to a heating element associated with a phase change material to transition the phase change material into a conductive state representative of a one bit stored in the memory cell, or applying a reset energy pulse to the heating element to transition the phase change material into a nonconductive state representative of a zero bit stored in the memory cell, wherein the phase change material can include a first amount of a phase change alloy doped with a second amount of carbon and a third amount of platinum. Example operation 2004 represents reading, by the system, the memory cell, including applying a read voltage pulse to a first end of the phase change material to determine whether a nonnegligible amount of current flows through the phase change material to a second end of the phase change material as a result of the phase change material being in the conductive state, representative of the one bit having been stored in the memory cell, or whether a negligible amount of current flows through the phase change material as a result of the phase change material being in the nonconductive state, representative of the zero bit having been stored in the memory cell.

The writing can be a first writing operation, the first writing operation can apply the set energy pulse to transition the phase change material to the conductive state, and further operations can include, in a second writing operation, applying, by the system, the reset energy pulse to transition the phase change material from the conductive state to the nonconductive state.

The writing can be a first writing operation, the first writing operation can apply the reset energy pulse to transition the phase change material to the nonconductive state, and further operations can include, in a second writing operation, applying, by the system, the set energy pulse to transition the phase change material from the nonconductive state to the conductive state.

The memory cell can be one memory cell of an array of memory cells, and applying the read voltage pulse to the first end of the phase change material can include applying the read voltage pulse to a bitline coupled to the first end of the phase change material.

One or more implementations can be embodied in a memory cell, including a phase change material electrically coupled to a bitline, and a heating element coupled to the bitline. The heating element can be controllable to set the phase change material to a conductive state, which corresponds to a first bit value, based on a set voltage pulse obtained via a heating element to apply first heat energy to the phase change material for a set pulse duration, or reset the phase change material to a nonconductive state, which corresponds to a second bit value, based on a reset voltage pulse obtained via heating element to apply second heat energy to the phase change material for a reset pulse duration, wherein the reset voltage pulse has a different voltage level from the set voltage pulse, wherein the set pulse duration can be different from the reset pulse duration. The phase change material can include a first amount of a phase change alloy material doped with a second amount of carbon and a third amount of platinum.

The set pulse duration can set the phase change material to the conductive state in a shorter length of time relative to a corresponding longer set pulse duration used to set a corresponding phase change alloy material, that is not doped with the second amount of carbon and the third amount of platinum, to a corresponding conductive state.

A read voltage pulse applied to the bitline, when the phase change material is set in the conductive state, can result in a nonnegligible current flow through the phase change material to facilitate readout of the first bit value, and the read voltage pulse applied to the phase change material, when the phase change material reset in the nonconductive state, can result in a negligible current flow through the phase change material to facilitate readout of the second bit value.

The first amount of the phase change alloy can include an amount of antimony telluride, the second amount of the carbon can include between about twelve to twenty-five percent of the amount of the antimony telluride, and the third amount of the platinum can include between about two to six percent of the amount of the antimony telluride.

The memory cell further can include thermally conductive dielectric material between the heating element and the phase change material.

The memory cell further can include a substrate, and thermally resistive dielectric material between the heating element and the substrate.

As can be seen, the technology described herein facilitates a phase change material-based memory unit cell. By doping phase change material (e.g., Sb2Te3) with carbon and platinum, the SET operation time can be significantly reduced, bringing it closer to the RESET time. This addresses one of the primary challenges in PCM technology, where SET operations typically have much longer latencies. Further, an efficient heat management approach can be included in the phase change memory unit cell design by incorporating a thermally resistive dielectric layer that minimizes heat loss to the substrate during SET and RESET operations. This provides precise control over phase transitions, improving the performance of the PCM cell. The faster performance of phase change memory cells, particularly the reduced SET time, makes this memory technology highly suitable use in nonvolatile memory (NVM) in computers. At the same time, the rapid and reliable data storage and retrieval capabilities of the change memory cells can enhance the performance of AI accelerators.

What has been described above include mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. M any modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A storage device, comprising:
a memory cell, comprising:
a phase change material; and
a heating element controllable to:
transfer first heat via a set pulse to the phase change material to transition the phase change material into a conductive state, in which a read voltage pulse applied to the phase change material results in a nonnegligible current flow, through the phase change material, that corresponds to a first bit value, or
transfer second heat via a reset pulse to the phase change material to transition the phase change material into a nonconductive state, in which the read voltage pulse applied to the phase change material results in a negligible current flow, through the phase change material, that corresponds to a second bit value that is different from the first bit value,
wherein the phase change material comprises a first amount of a phase change alloy doped with a second amount of carbon and a third amount of platinum, to result in the phase change material transitioning to the conductive state via the set pulse with a shorter set pulse duration, relative to a longer set pulse duration used to transition a corresponding phase change alloy that is not doped, to a corresponding conductive state.

2. The device of claim 1, wherein the first amount of the phase change alloy comprises an amount of antimony telluride, and wherein the second amount of the carbon comprises between about twelve to twenty-five percent of the amount of the antimony telluride.

3. The device of claim 1, wherein the first amount of the phase change alloy comprises an amount of antimony telluride, and wherein the third amount of the platinum comprises between about two to six percent of the amount of the antimony telluride.

4. The device of claim 1, wherein the first amount of the phase change alloy comprises an amount of antimony telluride, wherein the second amount of the carbon comprises between about twelve to twenty-five percent of the amount of the antimony telluride, and wherein the third amount of the platinum comprises between about two to six percent of the amount of the antimony telluride.

5. The device of claim 1, wherein the first bit value is a one bit value, and wherein the second bit value is a zero bit value.

6. The device of claim 1, wherein the memory cell comprises a substrate, and wherein the device comprises a thermally resistive dielectric material between the heating element and the substrate.

7. The device of claim 5, wherein the memory cell comprises a thermally conductive dielectric material between the heating element and the phase change material.

8. The device of claim 1, wherein the memory cell comprises a bitline and a wordline, wherein the heating element is coupled to the bitline, wherein the phase change material is coupled to the bitline, and wherein an access device is coupled to the wordline to activate the memory cell to facilitate current flow through the phase change material and the access device.

9. The device of claim 8, wherein when activated by the access device, in the conductive state of the phase change material, the read voltage pulse results in the nonnegligible current flow through the phase change material that corresponds to the first bit value, and wherein, in the nonconductive state of the phase change material, the read voltage pulse results in the negligible current flow through the phase change material that corresponds to the second bit value.

10. The device of claim 1, wherein the phase change material junction remains latched in the conductive state or the nonconductive state following completion of the set pulse or the reset pulse, respectively, until the heating element is controlled to transfer third heat to the phase change material junction via a next set pulse, or transfer fourth heat to the phase change material junction via a next reset pulse.

11. A method, comprising:
writing, by a system comprising at least one controller, information to a memory cell, comprising applying a set energy pulse to a heating element associated with a phase change material to transition the phase change material into a conductive state representative of a one bit stored in the memory cell, or applying a reset energy pulse to the heating element to transition the phase change material into a nonconductive state representative of a zero bit stored in the memory cell, wherein the phase change material comprises a first amount of a phase change alloy doped with a second amount of carbon and a third amount of platinum; and
reading, by the system, the memory cell, comprising applying a read voltage pulse to a first end of the phase change material to determine whether a nonnegligible amount of current flows through the phase change material to a second end of the phase change material as a result of the phase change material being in the conductive state, representative of the one bit having been stored in the memory cell, or whether a negligible amount of current flows through the phase change material as a result of the phase change material being in the nonconductive state, representative of the zero bit having been stored in the memory cell.

12. The method of claim 11, wherein the writing is a first writing operation, wherein the first writing operation applies the set energy pulse to transition the phase change material to the conductive state, and further comprising, in a second writing operation, applying, by the system, the reset energy pulse to transition the phase change material from the conductive state to the nonconductive state.

13. The method of claim 11, wherein the writing is a first writing operation, wherein the first writing operation applies the reset energy pulse to transition the phase change material to the nonconductive state, and further comprising, in a second writing operation, applying, by the system, the set energy pulse to transition the phase change material from the nonconductive state to the conductive state.

14. The method of claim 11, wherein the memory cell is one memory cell of an array of memory cells, and wherein the applying of the read voltage pulse to the first end of the phase change material comprises applying the read voltage pulse to a bitline coupled to the first end of the phase change material.

15. A memory cell, comprising:
a phase change material electrically coupled to a bitline; and
a heating element coupled to the bitline, the heating element controllable to:
set the phase change material to a conductive state, which corresponds to a first bit value, based on a set voltage pulse obtained via a heating element to apply first heat energy to the phase change material for a set pulse duration, or
reset the phase change material to a nonconductive state, which corresponds to a second bit value, based on a reset voltage pulse obtained via heating element to apply second heat energy to the phase change material for a reset pulse duration, wherein the reset voltage pulse has a different voltage level from the set voltage pulse, wherein the set pulse duration is different from the reset pulse duration, and
wherein the phase change material comprises a first amount of a phase change alloy material doped with a second amount of carbon and a third amount of platinum.

16. The memory cell of claim 15, wherein the set pulse duration sets the phase change material to the conductive state in a shorter length of time relative to a corresponding longer set pulse duration used to set a corresponding phase change alloy material, that is not doped with the second amount of carbon and the third amount of platinum, to a corresponding conductive state.

17. The memory cell of claim 15, wherein a read voltage pulse applied to the bitline, when the phase change material is set in the conductive state, results in a nonnegligible current flow through the phase change material to facilitate readout of the first bit value, and wherein the read voltage pulse applied to the phase change material when the phase change material reset in the nonconductive state, results in a negligible current flow through the phase change material to facilitate readout of the second bit value.

18. The memory cell of claim 15, wherein the first amount of the phase change alloy comprises an amount of antimony telluride, wherein the second amount of the carbon comprises between about twelve to twenty-five percent of the amount of the antimony telluride, and wherein the third amount of the platinum comprises between about two to six percent of the amount of the antimony telluride.

19. The memory cell of claim 15, further comprising thermally conductive dielectric material between the heating element and the phase change material.

20. The memory cell of claim 15, further comprising a substrate, and thermally resistive dielectric material between the heating element and the substrate.
